(19) United States
(12) Patent Application Publication
(10) Pub. No.: US 2022/0137158 A1
(43) Pub. Date: May 5, 2022

(54) CONTACTLESS MAGNETIC SENSING SYSTEM AND METHOD

(71) Applicant: Haechitech Corporation, Cheongju-si (KR)

(72) Inventor: Eun Joong KIM, Seoul (KR)

(73) Assignee: Haechitech Corporation, Cheongju-si (KR)

(21) Appl. No.: 17/518,774

(22) Filed: Nov. 4, 2021

(30) Foreign Application Priority Data
Nov. 4, 2020 (KR) 10-2020-0145663

(51) Int. Cl. G01R 33/02

(52) U.S. Cl. CPC G01R 33/0206

(57) ABSTRACT

Disclosed are a contactless magnetic sensing system and method. Disclosed are a sensing system and method capable of extracting a rotation angle without a problem although the center axis of a rotating magnet is separated and disposed from an extension line in a detection direction of a Z-axis magnetic sensor or a center axis of the magnetic sensor.

### BACKGROUND

### 1. Technical Field

The present disclosure relates to a contactless magnetic sensing system and method, and more particularly, to magnetic sensors capable of detecting a motion in a three-dimensional (3-D) space, and a system including the magnetic sensors, and a sensing method thereof.

### 2. Related Art

In a comparison of performance between mobile devices, a comparison of camera functions, the smoothness of an operation attributable to the installation of various apps, the maximization of storage performance, etc. recently become gradually more important than the superiority and inferiority of a communication function. Furthermore, with the development of the semiconductor technology, physiological information of the human body obtained by several sensors mounted on a mobile device can be processed within the mobile device. A technology is further variously applied, which is intended to obtain information on a motion of a mobile device by using a 3-D sensor or a three-axis sensor and to further increase the utilization of the mobile device by incorporating the information into the mobile device is further variously applied.

Hereinafter, the background technology of the present disclosure is described.

FIG. 1 illustrates a rotating magnet having a round shape and capable of rotating around a rotation axis and a 3-D coordinate system. It is assumed that the N pole and the S pole of the rotating magnet are divided at the center of a circle, for convenience sake, because the N pole and the S pole cannot be separated. It is assumed that a virtual rotation axis is placed at the center of the rotating magnet in order to represent the rotation of the rotating magnet. As everyone knows from common sense, a magnetic line of force indicative of a magnetic field starts from the N pole and reaches the S pole. FIG. 2 illustrates the directions of such magnetic lines of force as lines to which arrows are added.

When the rotating magnet having the rotation axis placed at the origin point of the 3-D coordinate system is viewed from the top, that is, when an X-Y plane is viewed from the top, the rotating magnet seems a circle as in FIG. 3. When rotating around the axis, the rotating magnet has the shape of rotating circle. Assuming that the N pole is placed on the upper side and the S pole is placed on the lower side right before the rotation starts, an angle formed by the N pole and the S pole is assumed to be 0. When the rotating magnet rotates, the direction of the magnetic field also rotates. In the coordinate system of FIG. 3, if the intensity of a magnetic field at the origin point is measured, a Y-axis component of the magnetic field becomes a maximum and an X-axis component of the magnetic field becomes a minimum when a rotation angle is 0 degree. The Y-axis component of the magnetic field becomes a minimum and the X-axis component of the magnetic field becomes a maximum when the rotation angle is 90 degrees. A Z-axis component of the magnetic field is not changed because the rotation is performed on the X-Y plane.

Accordingly, when rotation is performed once from 0 degree to 360 degrees and the rotation axis is coincident with an extension line of a Z axis, that is, in the case of an ON-AXIS, the X-axis component is represented as a sine waveform, the Y-axis component is represented as a cosine waveform, and the Z-axis component is not changed in a change in the magnitude of magnetic fields. Such changes in the waveforms of the X, Y and Z axes are illustrated in FIG. 4. In the waveform diagrams of FIG. 4, a horizontal axis indicates a rotation angle, and a vertical axis indicates the magnitude of a magnetic field, that is, magnetism. Such a graph may be detected using a magnetic sensor, such as a hall sensor using a hall effect. For reference, the term “ON-AXIS” collectively refers to a case where the extension line of the X axis or the Y axis in addition to the extension line of the Z-axis is coincident with the rotation axis of the rotating magnet, but the Z axis is described as an example for convenience of description.

A change in magnetism is detected by magnetic sensors disposed at the same point. For example, magnitudes of magnetism in X-axis, Y-axis and Z-axis directions are measured by three sensors disposed at the same point, for detecting magnetic fields in the X-axis, Y-axis and Z-axis directions, that is, an X-axis sensor, a Y-axis sensor and a Z-axis sensor, respectively. The X-axis sensor, the Y-axis sensor and the Z-axis sensor are called 3-D sensors, for convenience sake, because a magnetic field in the 3-D space can be measured by the three sensors. As illustrated in FIG. 5 as an example, assuming that a rotating magnet is disposed at the origin point and X-axis, Y-axis and Z-axis sensors for measuring magnetic fields in X-axis, Y-axis and Z-axis directions, respectively, are disposed at the origin point, the three sensors measure 3-D magnetic field vector values according to a rotation movement of the rotating magnet. The vector value may include amplitude and phase of a magnetic field.

When the rotation axis is coincident with the Z-axis extension line of the origin point in the coordinate system, that is, in the case of the ON-AXIS, relative ratios of X-axis, Y-axis and Z-axis components of magnetic fields may be represented as three angular diagrams as in FIG. 6. In particular, in the angular diagram (i.e., an X-Y diagram) representing the X-axis and Y-axis components of the magnetic fields, a value of the diagram is coincident with an angle formed by the rotating magnet and the X axis. In the angular diagrams illustrated in FIG. 6, when rotation angles are 0 degree, 90 degrees, 180 degrees, and 270 degrees, [X,Y] components each indicative of a ratio of amplitude may be represented as [0,1], [1,0], [0,−1], and [−1,0], respectively. In this case, the values of 0, 1, and −1 within “[ ]” indicate a minimum value, a positive maximum value, and a negative maximum value, respectively. Values within “[ ]” at other given angles are within the range from −1 to 1. That is, the values within “[ ]” correspond to outputs of the sensors. An angle of the rotating magnet can be accurately known from the outputs. More accurately, an angle of the rotating magnet can be known by applying arctangent to a value within “[ ].”

In the case of the ON-AXIS, as illustrated in FIG. 6, the X-Y angular diagram has a complete circular shape having a center point as the origin point. The reason for this is that maximum and minimum values of magnetic fields of the X-axis and Y-axis components are the same and only phases thereof are different. The X-Z and Y-Z angular diagrams each have a straight-line shape because the magnetic field of the Z-axis component is not present or is constant.

In general, when a motion is detected using a magnetic sensor, a rotating magnet is disposed on the magnetic sensor as ON-AXIS as illustrated in FIG. 6. A change in the direction of magnetic flux attributable to the rotation of the rotating magnet is read using the magnetic sensor. In general, when such a sensing technology is applied to a mobile device, etc., the magnetic sensor is included in a substrate or a semiconductor integrated circuit along with subsequent circuits. Accordingly, the rotating magnet is also disposed on the semiconductor integrated circuit in the case of the ON-AXIS.

However, such a method has a disadvantage in that it is difficult to apply the method to a mobile device that gradually becomes light, thin, short, and small because the fixture and rotation axis of the rotating magnet are not coincident with each other and the rotating magnet occupies much height space. Accordingly, a location of the rotating magnet is not limited on an integrated circuit, but there is an increasing need to dispose a rotating magnet at a more free location.

### PRIOR ART DOCUMENT

[Patent Document]

Patent Document: U.S. Pat. No. 10,551,222 B2 (Feb. 4, 2020)

### SUMMARY

Various embodiments are directed to providing a contactless magnetic sensing system and method capable of increasing mountability and a degree of freedom in the arrangement of parts by freely disposing a rotating magnet without limiting a location of an integrated circuit or a substrate including a magnetic sensor.

Also, various embodiments are directed to increasing a degree of freedom in the space of an electronic part by allowing a rotation axis of a rotating magnet to be disposed away from a central part of a magnetic sensor.

In an embodiment, a contactless magnetic sensing system may include magnetic sensors configured to detect magnetic fields in a three-axis direction, an extension line in the three-axis direction at an origin point at which the magnetic sensors are disposed, a rotating magnet having a rotation axis separated from the extension line, and a substrate in which the magnetic sensors are disposed.

In an embodiment, a contactless magnetic sensing method may include a step of rotating, by a rotating magnet, around a rotation axis, a sensing step of detecting magnetic fields in two axis directions of an origin point at which sensors are disposed, a step of extracting a parameter based on information detected in the sensing step, a step of converting the detected information based on the parameter, and a step of extracting a rotation angle based on the conversion.

According to an embodiment of the present disclosure, space can be reduced and the mountability of the rotating magnet as an electronic part can be improved because a rotating magnet is separated from a substrate on which a magnetic sensor is mounted and disposed over the substrate.

### BRIEF DESCRIPTION OF THE DRAWINGS

FIG. 1 illustrates a rotating magnet and a coordinate system thereof.

FIG. 2 illustrates directions of magnetic fields when a rotating magnet is viewed on the side.

FIG. 3 illustrates the rotating magnet when viewed from the top and a coordinate system thereof.

FIG. 4 illustrates 3-D axis components of magnetic fields in the rotating magnet.

FIG. 5 illustrates the case of the ON-AXIS.

FIG. 6 illustrates angular diagrams in the case of the ON-AXIS.

FIG. 7 illustrates cases of an OFF-AXIS.

FIG. 8 illustrates angular diagrams between axes which may appear in the case of the OFF-AXIS.

FIG. 9 illustrates the influences of offsets attributable to an external magnetic field in OFF-AXIS angular diagrams.

FIG. 10 illustrates an example of the OFF-AXIS in which a rotation axis of a rotating magnet is separated from a center point of a substrate on which a magnetic sensor is mounted.

FIG. 11 illustrates an example of the conversion of an angular diagram in the case of the OFF-AXIS.

FIG. 12 illustrates another example of the conversion of an angular diagram in the case of the OFF-AXIS.

FIG. 13 illustrates a contactless magnetic sensing system.

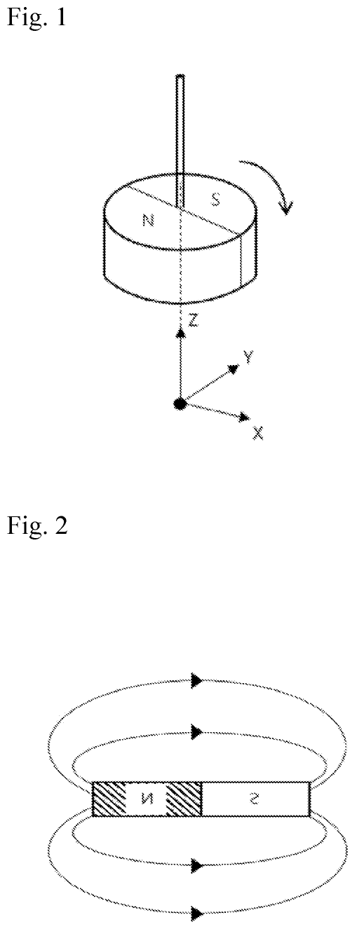

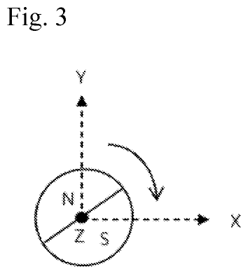

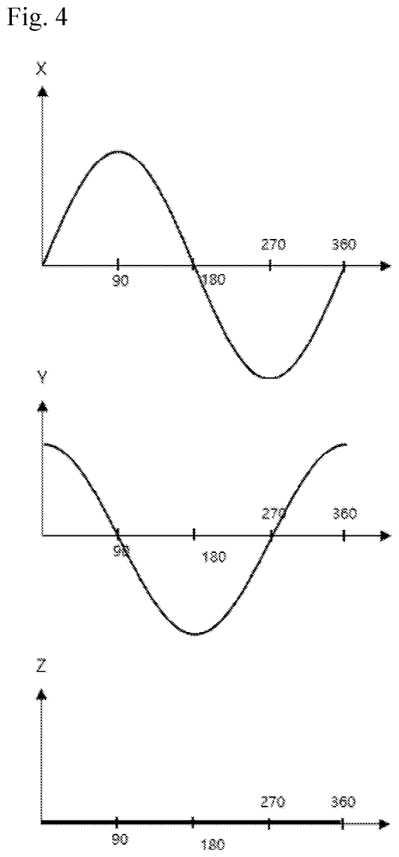

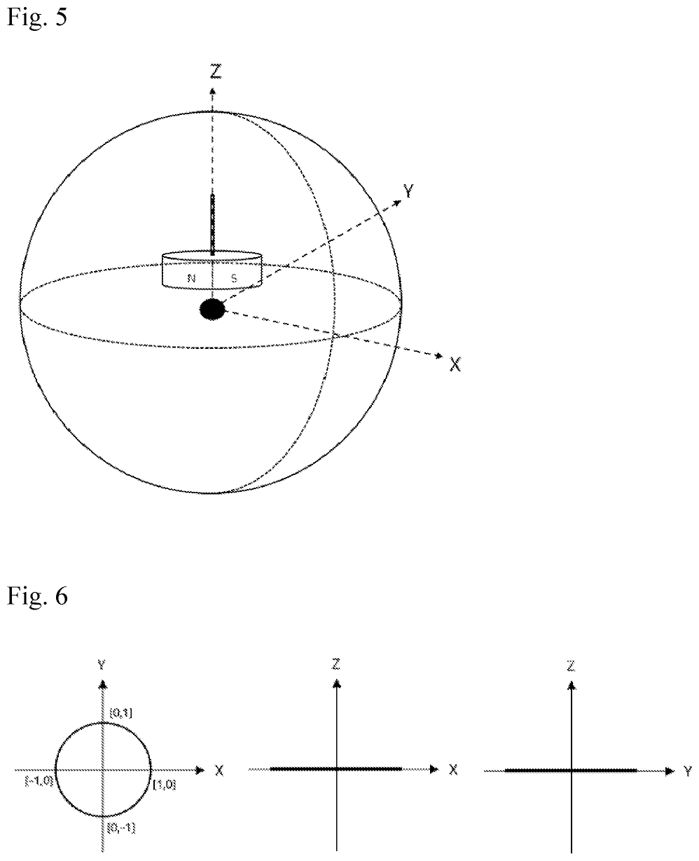

### DETAILED DESCRIPTION

Hereinafter, embodiments of the present disclosure are described in detail with reference to the accompanying drawings in order for a person having ordinary knowledge in the art to which the present disclosure pertains to easily carry out the present disclosure. In the drawings, the same reference numeral is used to refer to the same member throughout the specification.

In describing the present disclosure, a detailed description of a related known technology will be omitted if it is deemed to make the subject matter of the present disclosure unnecessarily vague.

Terms, such as a “first” and a “second”, may be used to describe various elements, but the elements are not restricted by the terms. The terms are used to only distinguish one element from the other element.

In an embodiment of the present disclosure, there are disclosed a contactless rotating magnet in which the axis of a rotating magnet is disposed away from the center of a magnetic sensor and a system thereof.

In the entire specification of the present disclosure, a term described as a “substrate” is used to collectively refer to a semiconductor integrated circuit or a printed circuit board on which a variety of types of magnetic sensors have been mounted or formed, a printed circuit board including a semiconductor integrated circuit, and various modules which may be mounted on a completed electronic product as parts.

Furthermore, in the entire specification of the present disclosure, the meaning of an “origin point” or a “center point” refers to a point at which a magnetic sensor is present in order to measure the intensity of a magnetic field in a three-dimensional (3-D) space, and is for describing a 3-D space around an “origin point” for convenience of description.

Furthermore, in the present disclosure, an extension line of an axis is for describing a 3-D space, and may be a virtual line in which a point at which magnetic sensors are disposed is assumed to be an origin point.

In the present disclosure, unlike in a conventional technology, one given extension line among extension lines extending in a three-axis direction from a center point at which magnetic sensors are disposed and a rotation center axis of a rotating magnet are not coincident with each other, but are separated from each other. In the entire specification of the present disclosure, such inconsistency is represented as an “OFF-AXIS”, for convenience sake. For reference, the “OFF-AXIS” collectively refers to a case where an extension line of an X axis or a Y axis in addition to an extension line of a Z-axis and a rotation axis of a rotating magnet are not coincident with each other. In the present disclosure, however, only the Z axis is described as an example for convenience of description.

Researchers of the present disclosure have found that a rotating magnet does not have a problem with a function through proper detection and proper coordinate conversion although the rotating magnet is disposed in the OFF-AXIS.

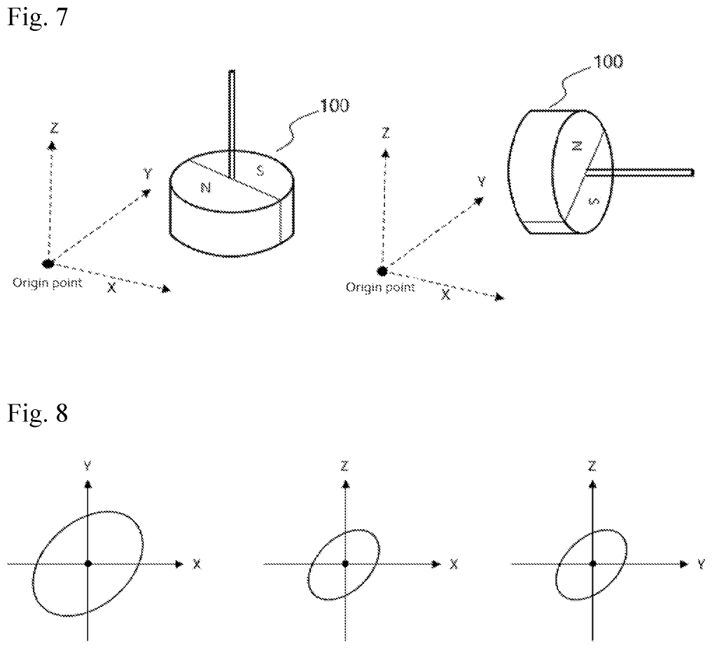

FIG. 7 illustrates some of several possible embodiments of the present disclosure. As may be seen from FIG. 7, a rotation axis of a rotating magnet 100 has been separated from the center point of a magnetic sensor, that is, the origin point of a 3-D coordinate system in an extension line of an axis direction. It is to be noted that the rotation axis of the rotating magnet is intended to merely indicate the rotation center of the rotating magnet and may be a virtual axis. The origin point of the 3-D coordinate system refers to a point at which 3-axis magnetic sensors for detecting a 3-D magnetic field are collected and disposed. As in the present disclosure, in the case of the OFF-AXIS, intensities of a magnetic field in an X axis direction and a magnetic field in a Y axis direction are relatively different. A degree of the difference varies depending on a degree of separation. Accordingly, a shape of an X-Y diagram may be changed from a circle to an oval, and all of maximum values of magnetic fields of an X-axis component, a Y-axis component and a Z-axis component may be changed. When the rotation axis of the rotating magnet 100 deviates from the Z axis or an extension line thereof (OFF-AXIS), a magnetic field starts to be detected by Z-axis magnetic sensors disposed at the origin point because a magnetic field component of the Z axis is no longer 0. Accordingly, as illustrated in FIG. 8, shapes of two diagrams including the Z axis, that is, shapes of a Z-X diagram and a Z-Y diagram, are represented as small ovals.

An angular diagram refers to the intensity of a magnetic field on a plane formed by given two of three axes in a 3-D space. For example, if two axes of an angular diagram are X and Y, an angular diagram refers to an X-axis component and Y-axis component of a magnetic field measured on an X-Y plane.

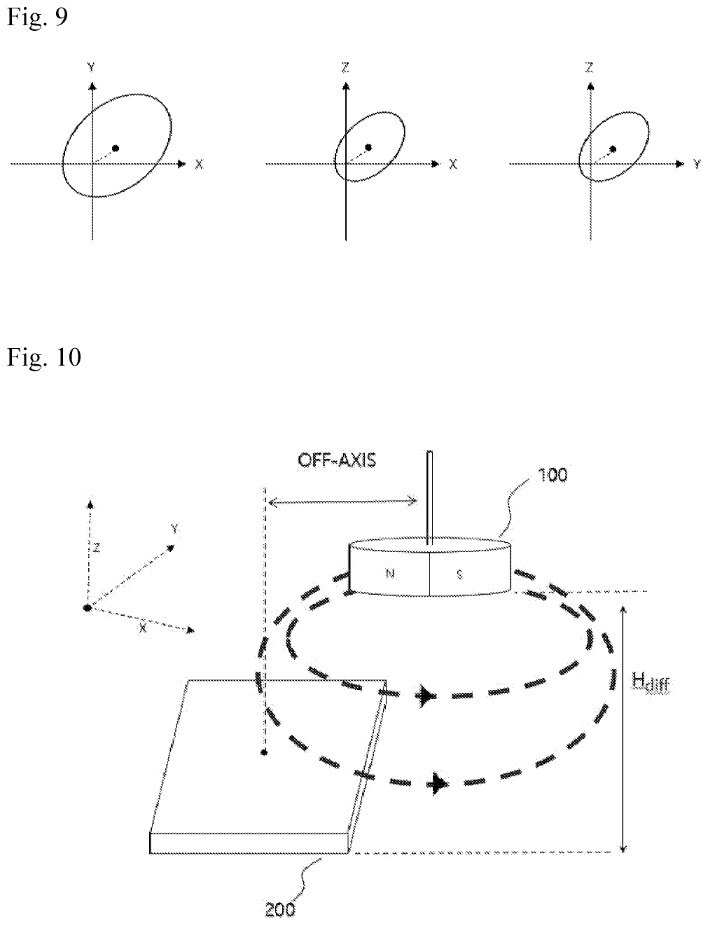

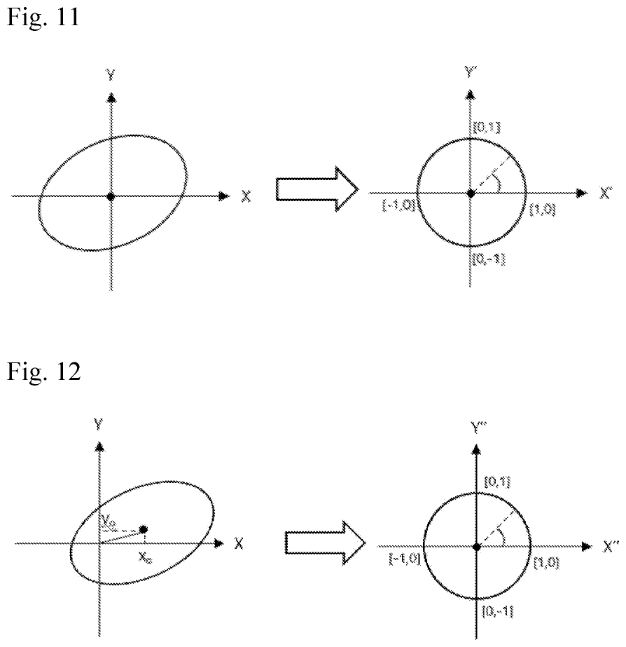

A magnetic sensor disposed at the origin point of a 3-D space may be influenced by another external magnetic field separately from a magnetic field attributable to a rotating magnet. The external magnetic field refers to a magnetic field attributable to another device or a magnetic field attributable to other causes. In this case, an angular diagram is represented as an offset because the center point of an oval deviates from the origin point of the angular diagram as illustrated in FIG. 9. A degree of the offset is proportional to a degree of interference of an external magnetic field. When the degree of interference is constant, the offset is also constant. An offset in an X-Y diagram may be calculated like Xoffset=(Xmax+Xmin)/2 or Yoffset=(Ymax+Ymin)/2. Offsets in other Z-Y and Z-X diagrams may also be similarly calculated.

In the present disclosure, even in the case of the OFF-AXIS, an axis direction component of a magnetic field varies at a cycle of 360 degrees. The same principle is applied to a case where an offset is present.

An angular diagram may be restored from an oval angular diagram to a circular angular diagram or an angular diagram having a shape close to a circle due to the aforementioned characteristics of the OFF-AXIS. Such restoration is converted from a distance between the origin point and the center point of an oval based on the following determinant.

$$( \begin{matrix}{x}^{′} \\ {y}^{′}\end{matrix} ) = ( \begin{matrix}a & b \\ c & d\end{matrix} ) ( \begin{matrix}x \\ y\end{matrix} ) \qquad ( 1 )$$

wherein

$$( \begin{matrix}{x}^{′} \\ {y}^{′}\end{matrix} )$$

is a value converted into a circle,

$$( \begin{matrix}x \\ y\end{matrix} )$$

is a value of an oval, and

$$( \begin{matrix}a & b \\ c & d\end{matrix} )$$

a parameter. Optimum conversion is to make equal maximum values of magnetic fields in the X axis and the Y axis. In this case, a diagram in which a value

$$( \begin{matrix}{x}^{′} \\ {y}^{′}\end{matrix} )$$

newly generated by the conversion is normalized and converted between −1 and 1 has a circular shape. The diagram having the circular shape directly indicates an angle formed by the rotating magnet 100 and the X axis. As may be seen from FIG. 10, the rotating magnet may be disposed at the same height (H_{diff}=0) as locations of substrates or may be disposed at a different height (H_{diff}>0) from the locations of the substrates, if necessary. Such various modified examples may be naturally derived from the aforementioned embodiment of the present disclosure. Even in this case, phase characteristics of the X-axis, Y-axis and Z-axis components of magnetic fields are maintained.

If an external magnetic field additionally exerts an influence as illustrated in FIG. 12, the influence appears as an offset in the angular diagram. Even in the case of the OFF-AXIS involving the offset, the oval angular diagram may be converted into a circular angular diagram by properly considering a value of the offset. In this case, the circular angular diagram is simply represented using the following equation.

$$( \begin{matrix}{x}^{″} \\ {y}^{″}\end{matrix} ) = ( \begin{matrix}{a}^{′} & {b}^{′} \\ {c}^{′} & {d}^{′}\end{matrix} ) ( \begin{matrix}x + x o \\ y + y o\end{matrix} ) \qquad ( 2 )$$

wherein

$$( \begin{matrix}{x}^{″} \\ {y}^{″}\end{matrix} )$$

is a value converted into a circle,

$$( \begin{matrix}x \\ y\end{matrix} )$$

is a value of an oval, and

$$( \begin{matrix}x o \\ y o\end{matrix} )$$

is a value of the offset.

$$( \begin{matrix}{a}^{′} & {b}^{′} \\ {c}^{′} & {d}^{′}\end{matrix} )$$

is a parameter used in a normalization process for converting the oval into the circle.

More precisely speaking mathematically, the aforementioned matrixes may always be converted into the circle accurately or a shape approximately close to the circle if the oval has only to be linear and continuous. The parameters may generally become constants or proper functions according to circumstances.

The aforementioned conversion process is described by stages and summarized as follows.

1. A step of rotating the rotating magnet around the rotation axis

2. A sensing step of detecting magnetic fields in two axis directions of the origin point at which magnetic sensors are disposed

3. An offset calculation step of checking a degree of interference attributable to an external magnetic field

4. A step of extracting a parameter based on information detected in the sensing step

5. A step of converting detected information by considering the parameter

6. A step of extracting a rotation angle based on the conversion

Among the steps, the offset calculation step is not necessary when interference attributable to an external magnetic field is not present. The step of extracting a rotation angle refers to the aforementioned arctangent calculation process.

From several embodiments of the present disclosure, it may be seen that even in the case of the OFF-AXIS in which the rotation axis of the rotating magnet 100 has deviated from an extension line of the center of a substrate, an angle of the rotating magnet can be extracted regardless of a distance between the rotating magnet and the center of the substrate and a rotation angle can always be obtained although a rotation plane of the rotating magnet and the extension line of the center point of magnetic sensors in a three-axis direction form a given angle.

Furthermore, it may be seen that a shape of an angular diagram is changed into an oval or the center of the substrate has deviated from the origin point when the rotating magnet is disposed at a given location as in several embodiments of the present disclosure.

As may be seen from the aforementioned several embodiments of the present disclosure, in the case of the OFF-AXIS in which the rotation axis of a rotating magnet has been separated from the center of magnetic sensors or an extension line of the center thereof or the center of a substrate including magnetic sensors or an extension line of the center thereof, a magnetic field can be detected by the magnetic sensor regardless of an separated distance or an angle of the separation. Accordingly, information, such as coordinates of a motion in a 3-D space, an azimuth angle, etc. can be obtained.

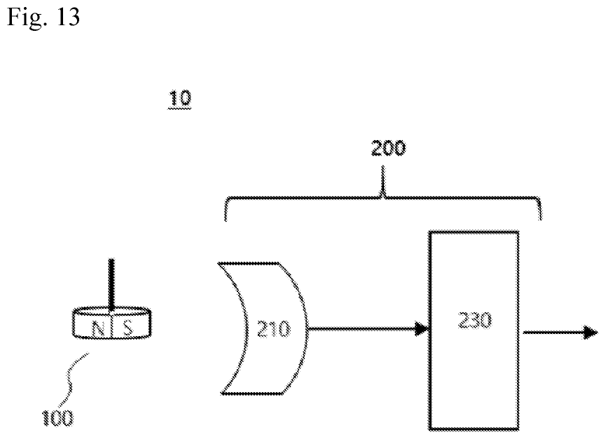

FIG. 13 illustrates a contactless magnetic sensing system of the present disclosure.

A magnetic field of the rotating magnet 100 is detected by magnetic sensors 210. The magnetic sensors 210 convert magnetic signals into corresponding electric signals. The magnetic sensors 210 have been illustrated as a single block, but include at least some of an X-axis magnetic sensor, a Y-axis magnetic sensor and a Z-axis magnetic sensor. The aforementioned conversion is achieved by a control calculation unit 230. Some or all of the magnetic sensors 210 and the control calculation unit 230 may be separately included in a substrate.

Although described above, in the entire specification of the present disclosure, it is to be noted that the term “substrate” may be used to collectively refer to a semiconductor integrated circuit or a printed circuit board on which a variety of types of magnetic sensors of the present disclosure have been mounted or formed, a printed circuit board including a semiconductor integrated circuit, and various modules which may be mounted on a completed electronic product as parts.

In the entire specification of the present disclosure, it is also to be noted that the term “substrate” is used as a meaning for indicating an element for maintaining the state in which a variety of types of magnetic sensors of the present disclosure have been mounted and fixed.

The control calculation unit 230 may perform other functions, for example, proper functions, such as the amplification or modulation of a signal, a comparison between signals, and analog-to-digital (AD) conversion, in addition to the conversion function.

As described above, according to an embodiment of the present disclosure or a core idea of the present disclosure, a rotating magnet may be separated and separated from a substrate on which magnetic sensors are mounted. Accordingly, it is advantageous to make a mobile device light, thin, short, and small because the mountability of the rotating magnet can be improved when being used as an electronic part.

The present disclosure has been described with reference to the embodiments illustrated in the accompanying drawings, but the embodiments are merely illustrative. A person having ordinary knowledge in the art will understand that various modifications and other equivalent embodiments are possible from the embodiments. Accordingly, the true technical range of protection of the present disclosure should be defined by the technical spirit of the appended claims.

### DESCRIPTION OF REFERENCE NUMERALS

10: contactless rotating magnetic sensor system
100: rotating magnet 200: substrate
210: magnetic sensors 230: control calculation unit

What is claimed is:

1. A contactless magnetic sensing system comprising:
magnetic sensors configured to detect magnetic fields in a three-axis direction;
an extension line in the three-axis direction at an origin point at which the magnetic sensors are disposed;
a rotating magnet having a rotation axis separated from the extension line; and
a substrate in which the magnetic sensors are disposed.

2. The contactless magnetic sensing system of claim 1, wherein the substrate is an integrated circuit.

3. The contactless magnetic sensing system of claim 1, wherein the substrate comprises one or more electronic parts and a connection line connecting the one or more electronic parts.

4. The contactless magnetic sensing system of claim 1, wherein the separation has a height difference according to a relative location between the substrate and the rotating magnet.

5. The contactless magnetic sensing system of claim 1, wherein the separation is disposed in parallel without a height difference between the substrate and the rotating magnet.

6. The contactless magnetic sensing system of claim 1, wherein in the separation, the extension line and the rotation axis form a given angle.

7. The contactless magnetic sensing system of claim 1, wherein the magnetic sensors convert, into an electric signal, data of a magnetic field generated by the rotating magnet.

8. The contactless magnetic sensing system of claim 1, wherein the rotation axis is a virtual structure for indicating a rotation of the rotating magnet.

9. The contactless magnetic sensing system of claim 1, wherein the substrate comprises a control calculation unit for calculating a change in the magnetic field detected by the magnetic sensors.

10. The contactless magnetic sensing system of claim 9, wherein the calculation comprises conversion by a determinant.

11. A contactless magnetic sensing method comprising:
a step of rotating, by a rotating magnet, around a rotation axis;
a sensing step of detecting magnetic fields in two axis directions of an origin point at which magnetic sensors are disposed;
a step of extracting a parameter based on information detected in the sensing step;
a step of converting the detected information based on the parameter; and
a step of extracting a rotation angle based on the conversion.

12. The contactless magnetic sensing method of claim 11, further comprising an offset calculation step of checking a degree of interference attributable to an external magnetic field.

13. The contactless magnetic sensing method of claim 12, further comprising a step of incorporating, into the step of converting the detected information, a value extracted in the offset calculation step.
